(19) United States
(12) Patent Application Publication
(10) Pub. No.: US 2004/0233637 A1
(43) Pub. Date: Nov. 25, 2004

(54) Slim type packaging structure with high heat dissipation

(76) Inventors: Kuang-Hsiung Chen, Chung-Li (TW); Wen-Chi Chiang, Chung-Li (TW); Ji-Ming Li, Chung-Li (TW); Wai-Chih Liu, Chung-Li (TW); Tien-Tzu Su, Chung-Li (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/441,203

(22) Filed: May 20, 2003

(51) Int. Cl. H05K 7/20

(52) U.S. Cl. 361/704; 361/717

(57) ABSTRACT

The invention provides a slim type packaging structure with high heat dissipation, which is to provide a hole on the surface of a substrate, and then a die is placed inside the hole. Besides, a plurality of wire is separately connected from the die to the substrate. Alternatively, a heat-dissipating panel with good conductivity can be placed inside the hole, and then the die is placed on the heat-dissipating panel. Thus, after the substrate is soldered on the circuit board, a direct heat-dissipating path can be formed between the die and the circuit board; therefore, the die can dissipate heat without passing through the substrate. Hence, the slim type packaging structure with high heat dissipation provided by the invention can achieve double effects of good heat dissipation and package volume slimming as well as have the advantages of low cost and simple design.

### BACKGROUND OF THE INVENTION

1. Field of the Invention

The invention relates to a packaging structure and, more particularly, to an ultra-slim type packaging structure with high heat dissipation.

2. Description of the Related Art

Downsizing semiconductor packaging has been a major goal pursued by people in the semiconductor industry. The area array of a substrate primary includes ball grid array (BGA) packaging and chip size packaging (CSP). In addition, there is a non-lead packaging called land grid array (LGA) packaging, which utilizes terminals as outer leads. Through LGA packaging technique without solder ball, not only can the wire wound of signals be simplified, but the dimension of circuit board can also be largely diminished, thereby achieving the purpose of downsizing. Moreover, through LGA, there is usually no need to use the kind of printed circuit board (PCB) that contains micro vias or dot pitch; therefore, low-cost PCB can be employed to decrease the cost and complexity of design.

Referring to FIG. 1, the conventional LGA packaging structure is first to adhere a die 12 to a substrate 10. Next, gold wires are used for wire bonding to connect the die 12 and the substrate 10. Then, after encapsulation, solder paste 16 is used for soldering the substrate 10 on the PCB 18. However, because the substrate 10 is normally a plastic material, the heat dissipation of die 12 must take the path of plastic substrate 10 and then go through PCB 18 for heat dissipation. Therefore, an undesired heat-dissipating difference can be generated. On the other hand, a substrate 10 made of metal material can be used instead of plastic substrate. However, although the die 12 can dissipate heat directly through the metal substrate 10 without taking other path, during the cutting process, the cutting knife is liable to be damaged because the metal substrate 10 is hard to be cut. Besides that, the weight of the whole package with metal substrate 10 will be heavier than that of with plastic substrate.

Furthermore, there is another conventional method for heat dissipation, which is to cover a metal heat-dissipating sheet on the die 12. Despite that such method can improve heat-dissipating problem, the overall size of the package will become larger and therefore fail to satisfy the demand for thinner packaging.

In viewing the problem, the invention provides a slim type packaging structure with high heat dissipation to cope with the conventional drawbacks.

### SUMMARY OF THE INVENTION

The primary and first object of the invention is to provide a slim type packaging structure with high heat dissipation, which is to provide a hole on the surface of a substrate, and then a die is placed inside the hole. Then, after the substrate is soldered on the PCB, the die will dissipate heat directly through the PCB without passing through the plastic substrate so that a best effect of heat dissipation can be achieved.

The second object of the invention is to provide a slim type packaging structure with high heat dissipation, whose functions are effective in dissipating heat and slimming package volume so that the problem existing in the prior art that the aforementioned functions cannot be achieved simultaneously can then be resolved.

The third object of the invention is to provide a simple design of slim type packaging structure with high heat dissipation that has the advantage of low cost.

According to the first aspect of the invention, a slim type packaging structure with high heat dissipation is provided on a PCB, wherein the slim type packaging structure includes a substrate, and a hole is provided thereon penetrating through the substrate. Besides, a die is placed inside the hole so that a direct heat-dissipating path can be formed between the die and the PCB. In addition, a plurality of wire is connected from the die to the substrate.

According to the second aspect of the invention, a slim type packaging structure with high heat dissipation includes a substrate, and a hole is also provided thereon. Besides, a heat-dissipating panel is placed inside the hole, and a die is provided on the heat-dissipating panel so that a direct heat-dissipating path is formed between the die and the PCB through the heat-dissipating panel. In addition, a plurality of wire is connected from the die to the substrate.

The objects and technical contents of the invention will be better understood through the description of the following embodiments with reference to the drawings.

### BRIEF DESCRIPTION OF THE DRAWINGS

FIG. 1 is a schematic diagram showing a conventional packaging structure.

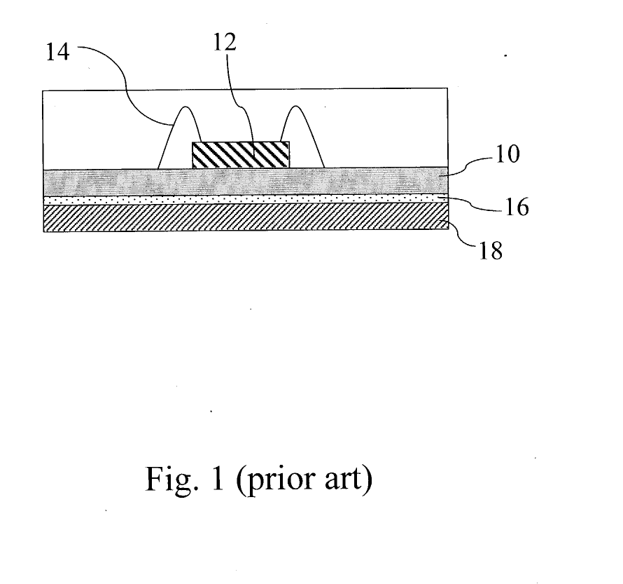

FIG. 2 is a sectional view of the packaging structure of the invention.

FIG. 3 is a sectional view of the packaging structure of the invention to be installed on a PCB.

FIG. 4 is a sectional view of the structure of another embodiment of the invention.

FIG. 5 is a sectional view of the structure of still another embodiment of the invention.

### DETAILED DESCRIPTION OF THE PREFERRED EMBODIMENTS

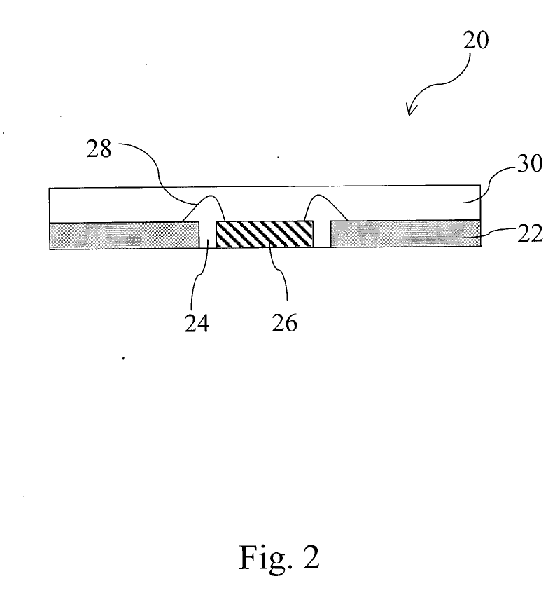

Referring to FIG. 2, which is a sectional view of the packaging structure of the invention, a slim type packaging structure 20 includes a substrate 22 made of plastic material, and a hole 24 is also provided on the substrate 22 penetrating through the substrate 22 to the surface of the substrate 22. Besides, a die 26 is placed inside the hole 24, and a plurality of wire 28 is separately connected from the bonding pads (not shown) on the surface of the die 26 to the substrate 22, wherein the wires 28 are usually gold wires. Also, a molding compound 30, normally made of epoxy resin, is provided covering the substrate 22 to wrap up the die 26 and the wires 28 so as to protect the connecting points between the die 26 together with their connected wires 28 and the substrate 22. Moreover, when processing the slim type packaging structure 20, a tape is adhered to the hole 24 at the backside of the substrate 22 so that a supporting structure is formed for installing the die 26, and the tape will be torn off before the end of processing.

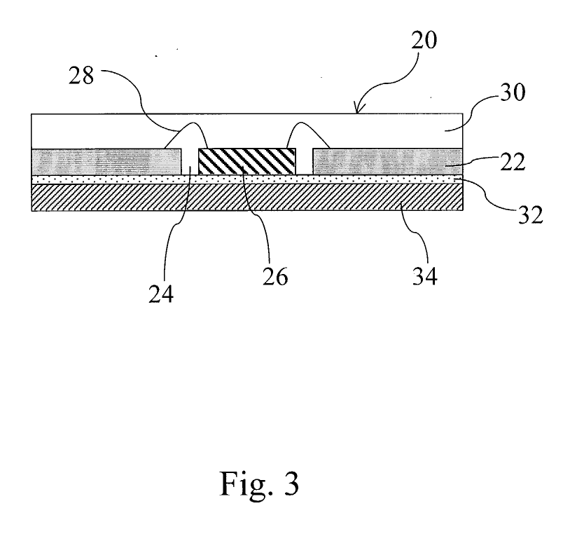

Furthermore, the slim type packaging structure of the invention usually is provided on the PCB 34 through soldering technique using solder paste 32 to form an aspect of structure shown in FIG. 3, wherein the solder paste 32 is a dielectric of high heat dissipation. Alternatively, silver glue, conductive glue, or resin that is a high heat-dissipating adhesive can be used in lieu. Moreover, in the slim type packaging structure 20, a direct heat-dissipating path can be formed between the die 26 and PCB 34 through the high heat-dissipating dielectric without passing through the plastic substrate 22; therefore, a best heat-dissipating effect can be obtained. Besides, because the die 26 is located inside the hole 24 of the substrate 22, the space of the whole packaging volume has become smaller and the size of the same has become thinner.

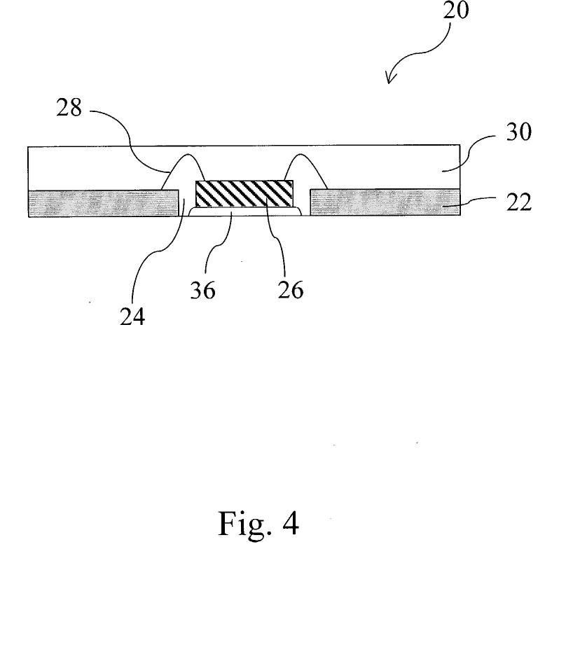

Also, referring to FIG. 4, which is a sectional view of the structure of another embodiment of the invention, a protecting layer 36 is further provided inside the hole 24 at the bottom surface of the die 26 and is normally made of epoxy resin to provide an reinforcing effect for protecting the die 26.

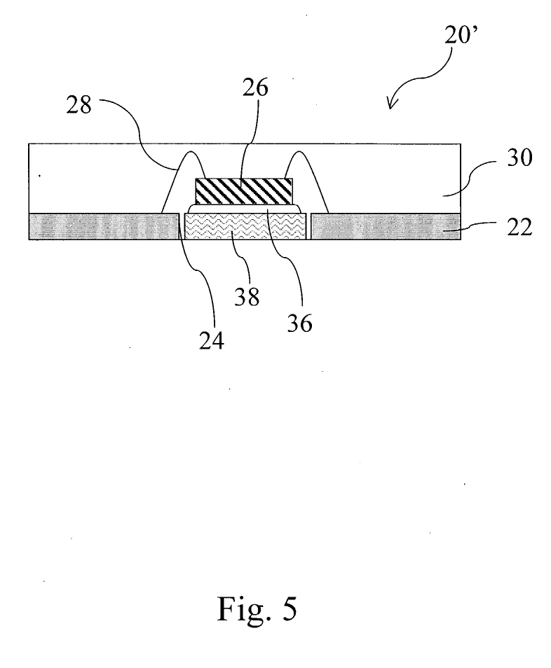

In order to reinforce the bonding force between the slim type packaging structure and the solder paste during the process of soldering, a heat-dissipating panel 38 made of good-conductivity material is provided inside the hole 24 of the substrate 22 of the slim type packaging structure, as shown in the embodiment of FIG. 5, wherein the material of heat-dissipating panel 38 is usually metal such as metal copper. Also, a protecting layer 36 is provided on the heat-dissipating panel 38, which is usually made of epoxy resin. Additionally, a die 26 is provided on the protecting layer 36, and a plurality of wire 28 is separately connected from a plurality of bonding pad (not shown) on the die 26 to the substrate 22, and a molding compound 30 is also provided covering the substrate 22 to wrap up the die 26 and the wires 28.

In the same way, after the slim type packaging structure 20′ is bonded to the PCB 34 through soldering technique, a direct heat-dissipating path can be formed between the die 26 and the PCB 34 through the heat-dissipating panel 38 that has good conductivity without passing through the plastic substrate 22 for heat dissipation. Therefore, the invention can achieve a good heat-dissipating effect. Also, unlike what has to be done in the prior art to cover the die with a metal heat-dissipating sheet, the invention can keep up with the demand for thinner packaging.

In conclusion, the invention is first to provide a hole on the substrate so that a die can be placed inside the hole or placed on a heat-dissipating panel inside the hole. Then, after the substrate is soldered on the PCB, the die can dissipate heat directly through the PCB without passing through the plastic substrate so as to achieve double effects of good heat dissipation and package volume slimming. Therefore, not only can the invention solve the conventional drawbacks, but it also has the advantage of being simply designed and therefore its cost can be lowered.

The embodiments above are only intended to illustrate the invention; they do not, however, to limit the invention to the specific embodiments. Accordingly, various modifications and changes may be made without departing from the spirit and scope of the invention as described in the appended claims.

What is claimed is:

1. A slim type packaging structure with high heat dissipation, which is provided on a circuit board, including:
a substrate, and a hole is provided thereon;
a die, located inside the hole, and a direct heat-dissipating path is formed between the die and the circuit board; and
a plurality of wire, which are separately connected from the die to the substrate.

2. The slim type packaging structure with high heat dissipation as claimed in claim 1, wherein a molding compound is covered on the substrate to wrap up the die and the wires.

3. The slim type packaging structure with high heat dissipation as claimed in claim 1, wherein a protecting layer is provided on the bottom surface of the die.

4. The slim type packaging structure with high heat dissipation as claimed in claim 3, wherein the protecting layer is made of epoxy resin.

5. A slim type packaging structure with high heat dissipation, which is provided on a circuit board, including:
a substrate, and a hole is provided thereon;
a heat-dissipating panel, placed inside the hole;
a die, placed on the heat-dissipating panel, and a direct heat-dissipating path is formed between the die and the circuit board through the heat-dissipating panel; and
a plurality of wire, which are separately connected from the die to the substrate.

6. The slim type packaging structure with high heat dissipation as claimed in claim 5, wherein a molding compound is covered on the substrate to wrap up the die and the wires.

7. The slim type packaging structure with high heat dissipation as claimed in claim 5, wherein a protecting layer is provided between the die and the heat-dissipating panel.

8. The slim type packaging structure with high heat dissipation as claimed in claim 7, wherein the protecting layer is made of epoxy resin.

9. The slim type packaging structure with high heat dissipation as claimed in claim 5, wherein the heat-dissipating panel is made of metal material.
